(19) United States
(12) Patent Application Publication
(10) Pub. No.: US 2026/0202760 A1
(43) Pub. Date: Jul. 16, 2026

(54) DISPERSION ENGINEERED BEAM MODIFIER FOR A METROLOGY SYSTEM

(71) Applicant: ASML NETHERLANDS B.V., Veldhoven (NL)

(72) Inventors: Saman JAHANI, Stamford, CT (US); Roxana REZVANI NARAGHI, Easton, CT (US)

(73) Assignee: ASML NETHERLANDS B.V., Veldhoven (NL)

(21) Appl. No.: 19/131,207

(22) PCT Filed: Nov. 14, 2023
(86) PCT No.: PCT/EP2023/081759

§ 371 Date: May 19, 2025

Related U.S. Application Data
(60) Provisional application No. 63/431,377, filed on Dec. 9, 2022.

(51) Int. Cl. G03F 7/00; G02B 1/00

(52) U.S. Cl. CPC G03F 7/706851; G02B 1/002; G03F 7/70266

(57) ABSTRACT

A beam modifier and metrology system having such a beam modifier is described. Metasurfaces are used to replace (or to augment) an existing objective lens to focus radiation such as light, tune a focal length, and/or correct aberrations in the metrology system. A metasurface is configured to receive a diffracted incident radiation beam, with the diffracted incident radiation beam having a known wavelength range and transmit separate narrower band sub-beams of radiation having a modified amplitude, phase, and/or polarization in comparison to the diffracted incident radiation. The metasurface includes different sub-portions configured to transmit the separate narrower band sub-beams of radiation. The different sub-portions are configured for different non-overlapping radiation wavelength bandwidths within the known wavelength range.

### CROSS-REFERENCE TO RELATED APPLICATION

This application claims priority of U.S. application 63/431,377 which was filed on 9 Dec. 2022, and which is incorporated herein in its entirety by reference.

### TECHNICAL FIELD

This description relates to a dispersion engineered beam modifier for a metrology system.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, deposition, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”-generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

A metrology system is described. Beam modifiers such as metasurfaces are used to replace (or to augment) an existing objective lens to focus radiation such as light, tune a focal length, and/or correct aberrations in the metrology system. A beam modifier (e.g., a metasurface) is configured to receive a diffracted incident radiation beam from a radiation source (with the diffracted incident radiation beam having a known wavelength range) and transmit separate narrower band sub-beams of radiation having a modified amplitude, phase, and/or polarization in comparison to the diffracted incident radiation. The beam modifier (e.g., metasurface) comprises different sub-portions configured to transmit the separate narrower band sub-beams of radiation. The different sub-portions are configured for different non-overlapping radiation wavelength bandwidths within the known wavelength range.

According to an embodiment, a beam modifier is provided. The beam modifier is configured to receive a diffracted incident radiation beam from a radiation source. The diffracted incident radiation beam has a known wavelength range. The beam modifier is configured to transmit separate narrower band sub-beams of radiation having a modified amplitude, phase, and/or polarization in comparison to the diffracted incident radiation beam. The beam modifier comprises different sub-portions configured to transmit the separate narrower band sub-beams of radiation. The different sub-portions are configured for different non-overlapping radiation wavelength bandwidths within the known wavelength range.

In some embodiments, the beam modifier is a metasurface, and the metasurface comprises nano-antennas, meta-atoms, scatterers, and/or nano-particles.

In some embodiments, the separate narrower band sub-beams of radiation comprise locally bandwidth narrowed non-overlapping sub-beams of radiation having the modified amplitude, phase, and/or polarization. Each sub-portion may be associated with a different color wavelength group and has a wavelength bandwidth for the associated color.

In some embodiments, the different sub-portions comprise adjacent local areas of a single unitary metasurface formed with nano-antennas, meta-atoms, scatterers, and/or nano-particles configured for specific non-overlapping radiation wavelength bandwidths.

In some embodiments, the nano-antennas, meta-atoms, scatterers, and/or nano-particles comprise blocks of material having heights, widths, lengths, and/or angles of rotation configured for a specific non-overlapping radiation wavelength bandwidth.

In some embodiments, the nano-antennas, meta-atoms, scatterers, and/or nano-particles comprise free form shapes configured for a specific non-overlapping radiation wavelength bandwidth.

In some embodiments, the different sub-portions are configured to focus transmitted radiation of a specific color on a target in a target location for that color.

In some embodiments, the different sub-portions are configured to collimate transmitted radiation of a specific color to form a collimated beam of radiation for that color.

In some embodiments, the different sub-portions are configured to disperse transmitted radiation of a specific color toward a target and a target location for that color.

In some embodiments, the beam modifier comprises a two dimensional (2D) array of adjacent sub-portions.

In some embodiments, the non-overlapping radiation wavelength bandwidths are fixed, and determined based on a pitch of a grating that generates the diffracted incident radiation beam, a grating height, wavelength, and/or a distance between the grating and the beam modifier.

In some embodiments, the distance between the grating and the beam modifier is configured to be adjusted based on the grating pitch and/or different operating wavelengths that correspond to different color wavelength groups associated with the different sub-portions.

In some embodiments, adjusting the distance between the grating and the beam modifier changes an angle of incidence of the diffracted incident radiation beam on the beam modifier.

In some embodiments, the beam modifier comprises a first metasurface, and a second metasurface spaced from the first metasurface along an optical path.

In some embodiments, a spacing of the second metasurface from the first metasurface controls a focal length, corrects a defocus, and/or corrects a wave front aberration of different colored narrowband sub-beams of radiation transmitted by the sub-portions.

In some embodiments, a mechanical system is configured to adjust the spacing.

In some embodiments, the beam modifier focuses the diffracted incident radiation beam, collimates the diffracted incident radiation beam, or divides the diffracted incident radiation beam into a series of non-overlapping radiation wavelength bands, each of which is focused at a different spot on a target.

According to another embodiment, a metrology system is provided. The metrology system comprises a radiation source configured to generate an incident radiation beam; a diffractor configured to diffract the incident radiation beam; and a beam modifier. The beam modifier is configured to receive a diffracted incident radiation beam from the radiation source and the diffractor. The diffracted incident radiation beam has a known wavelength range. The beam modifier is configured to transmit separate narrower band sub-beams of radiation having a modified amplitude, phase, and/or polarization in comparison to the diffracted incident radiation beam. The beam modifier comprises different sub-portions configured to transmit the separate narrower band sub-beams of radiation. The different sub-portions are configured for different non-overlapping radiation wavelength bandwidths within the known wavelength range. The diffracted incident radiation beam received by the beam modifier is spatially separated by color into different wavelength groups, and directed toward color corresponding ones of the different sub-portions.

In some embodiments, the diffractor comprises a grating. The diffracted incident radiation beam received by the beam modifier is spatially separated by color into different wavelength groups and directed toward color corresponding ones of the different sub-portions by the grating. A non-overlapping radiation wavelength bandwidth requirement is a function of a grating pitch.

In some embodiments, the metrology system further comprises a detector configured to receive reflected radiation after it has reflected off a target, and generate a detection signal. The reflected radiation comprises the separate narrower band sub-beams of radiation after they have been reflected off the target.

In some embodiments, the metrology system forms a portion of an alignment sensor and/or an overlay detection sensor. The alignment sensor and/or the overlay detection sensor is configured for a semiconductor wafer, and is used in a semiconductor manufacturing process.

According to another embodiment, a metrology method is provided. The method comprises one or more of the operations described above performed by the beam modifier and/or the metrology system.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example inspection system, according to an embodiment.

FIG. 4 schematically depicts an example metrology technique, according to an embodiment.

FIG. 5 illustrates the relationship between a radiation illumination spot of an inspection system and a metrology target, according to an embodiment.

FIG. 6 illustrates beam modifiers (e.g., metasurfaces), according to an embodiment.

FIG. 7 schematically illustrates separating an incident radiation beam into wavelength bands, according to an embodiment.

FIG. 8 illustrates a plot of local metasurface sub-portion bandwidth wavelength range, AA, as a function of height, h (see FIG. 6—a distance between a diffractor and a beam modifier), according to an embodiment.

FIG. 9 illustrates a beam modifier (e.g., metasurface) doublet, according to an embodiment.

FIG. 10 illustrates a beam modifier (e.g., a metasurface) configured to divide a diffracted incident radiation beam into a series of non-overlapping wavelength bands of radiation, each of which is focused at a different spot on a target, on a detector, and/or in another location, according to an embodiment.

FIG. 11 illustrates a metrology method, according to an embodiment.

FIG. 12 is a block diagram of an example computer system, according to an embodiment.

### DETAILED DESCRIPTION

In semiconductor device manufacturing, metrology operations typically include determining the position of a metrology target (or marks) and/or other target in a layer of a semiconductor device structure. This position is typically determined by irradiating a metrology target with radiation, and comparing characteristics of different diffraction orders of radiation reflected from the metrology target. Such techniques are used to measure overlay, alignment, and/or other parameters. Prior metrology systems use a bulky, multi-element objective to transmit radiation to a target such as a metrology mark, and reflect diffracted radiation from the metrology mark to a detector. These objectives increase the costs and size of a typical metrology system, cannot avoid chromatic aberration, and cannot correct all radiation beam aberrations.

Using metasurfaces to replace or augment a bulky objective in a metrology system, or to modify an incident radiation beam for integrated optics alignment sensors, is described in U.S. Provisional Patent Application No. 63/420,208 filed 28 Oct. 2022 (“Compact Optical Arrangement for a Metrology System”, and U.S. Provisional Patent Application No. 63/415,246, both of which are incorporated by reference in their entireties. Beam modifiers such as metasurfaces (also known as metalenses or flat lenses) are used to replace (or augment) an existing objective lens to focus radiation, tune a focal length, and/or correct aberrations in the metrology system, which enhances metrology system sensitivity. The metrology system is also more compact, lighter, and cheaper than prior systems. With the features described below, metrology and/or other systems that utilize beam modifiers such as metasurfaces are not limited to any specific grating pitches, or a specific and discrete set of wavelengths with limited bandwidths.

Beam modifiers comprising metasurfaces having square cross-section nano-posts, posts with holes in them, circular posts with rectangular holes in them, or any other combination of post and/or hole shapes can have high efficiency transmission and both normal and anomalous dispersion for visible or infrared radiation by changing (nano) post size(s). Metasurfaces are inherently narrowband, but it is possible to configure a metasurface for wider radiation wavelength ranges to achieve achromatic metasurfaces over 60-200 nm bandwidths. However, designing a high numerical aperture, but also relatively thin metasurface, which covers the entire range (e.g., much more than 60-200 nm) of a usable radiation spectrum, is challenging.

Advantageously, for many metrology systems, characteristics of an incident beam and diffracted radiation beams are known. For example, a beam waist at the focus, the diffraction angle and the beam distribution as a function of a grating pitch may be known. By considering known characteristics about a radiation beam, and by considering aspects of metasurface design, the beam modifiers (e.g., metasurfaces) described below are configured to function for an entire operating wavelength range of a typical metrology system, and be adjustable for focusing a radiation beam diffracted by a grating with an arbitrary pitch. The beam modifiers described below may be broadband metasurfaces (e.g., as a whole, configured for multicolored light) which are locally narrowband (e.g., having different sub-portions configured to transmit the separate narrower band—single color or shade of gray in this example—sub-beams of radiation), for example.

By way of a brief introduction, the description below relates to semiconductor device manufacturing and patterning processes. The following paragraphs also describe several components of systems and/or methods for semiconductor device metrology. These systems and methods may be used for measuring overlay, alignment, etc., in a semiconductor device manufacturing process, for example, or for other operations.

Although specific reference may be made in this text to the measurement of overlay, alignment, or other parameters, and the manufacture of integrated circuits (ICs) for semiconductor devices, it should be understood that the description herein has many other applications. For example, it may be employed in the manufacture of integrated optical systems, guidance and detection patterns for magnetic domain memories, display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

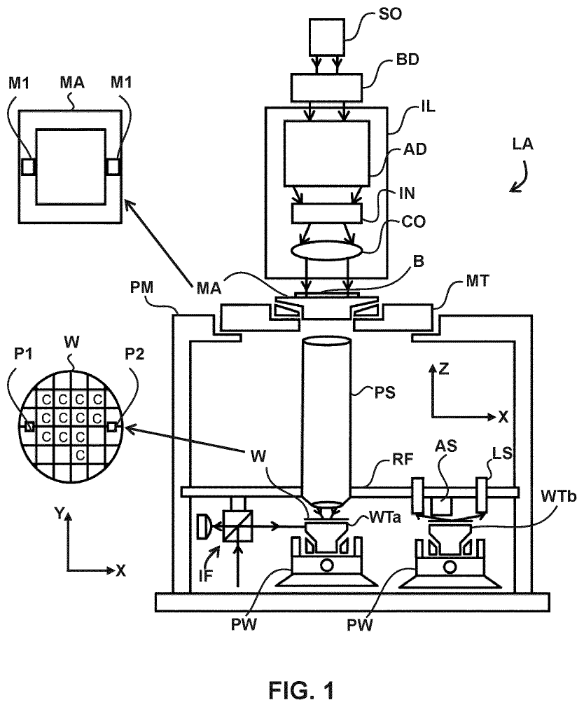

FIG. 1 schematically depicts an embodiment of a lithographic apparatus LA. The apparatus comprises an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” should be broadly interpreted as encompassing any type of projection system, including refractive, reflective, catadioptric, magnetic, electromagnetic, and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system.”

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be conducted on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein with respect to lithography encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

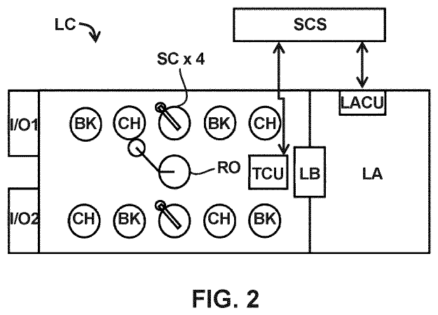

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on one or more dedicated metrology targets provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. Applications of this diffraction-based metrology include the measurement of overlay, alignment, etc. For example, overlay and/or alignment can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)).

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

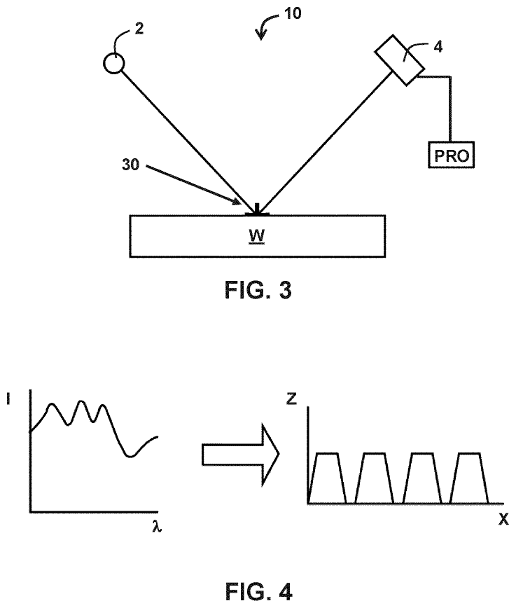

FIG. 3 depicts an example metrology (inspection) system 10 that may be used to detect overlay, alignment, and/or perform other metrology operations. It comprises a radiation or illumination source 2 which projects or otherwise irradiates radiation onto a substrate W (e.g., which may typically include a metrology mark). The redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 4. The sensor may generate a metrology signal conveying metrology data indicative of properties of the reflected radiation. From this data, the structure or profile giving rise to the detected spectrum may be reconstructed by one or more processors PRO, a generalized example of which is shown in FIG. 4, or by other operations.

As in the lithographic apparatus LA in FIG. 1, one or more substrate tables (not shown in FIG. 4) may be provided to hold the substrate W during measurement operations. The one or more substrate tables may be similar or identical in form to the substrate table WT (WTa or WTb or both) of FIG. 1. In an example where inspection system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., a metrology mark), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical metrology measurements, a target (portion) 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist.

The bars, pillars, vias, and/or other features may be etched into or on the substrate (e.g., into one or more layers on the substrate), deposited on a substrate, covered by a deposition layer, and/or have other properties. Target (portion) 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment.

For example, the measured data from target 30 may indicate overlay for a layer of a semiconductor device. The measured data from target 30 may be used (e.g., by the one or more processors PRO and/or other processors) for determining one or more semiconductor device manufacturing process parameters based the overlay, and determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target design, a semiconductor device design, an intensity of the radiation, an incident angle of the radiation, a wavelength of the radiation, a pupil size and/or shape, a resist material, and/or other process parameters.

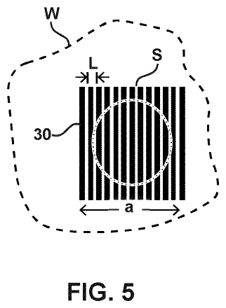

FIG. 5 illustrates a plan view of a typical target (e.g., metrology mark) 30, and the extent of a typical radiation illumination spot S in the system of FIG. 4. Typically, to obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on axis or off axis directions.

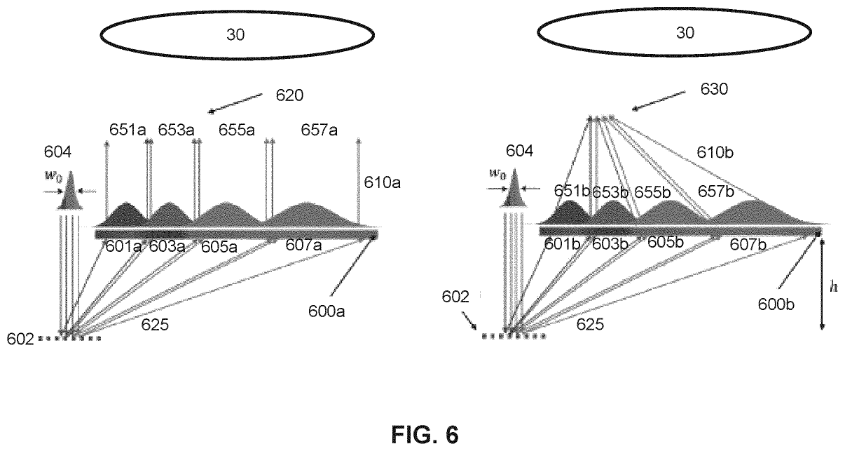

FIG. 6 illustrates beam modifiers 600a and 600b. In this example, beam modifiers 600a and/or 600b are broadband metasurfaces (e.g., as a whole, configured for multicolored light) which are locally narrowband (e.g., having different sub-portions configured to transmit the separate narrower band—single color or shade of gray in this example—sub-beams of radiation), for example. Different radiation wavelength ranges or bands are shown as different shades of gray in FIG. 6. Local operating wavelengths for the different sub-portions of the beam modifiers are defined by how light is diffracted. For example, if an incident radiation beam 604 is a plane wave and the beam modifier 600a and/or 600b (e.g., metasurface) is in far-field, each point the metasurface operates at a single wavelength. However, for a Gaussian input beam 604, at each point, the metasurface has a finite wavelength bandwidth, Δλ, which is a function of the incident radiation beam 604 waist, w₀.

Beam modifiers 600a or 600b may be used in a metrology system such as system 10 shown in FIG. 3 to replace or augment an objective configured for directing radiation to or from one or more metrology targets 30, such as one or more diffraction grating targets. The radiation may be used to obtain images of the metrology targets, and/or for other uses. The radiation may comprise illumination such as light and/or other radiation. A target 30 may comprise one or more metrology marks, such as diffraction grating targets, formed in a substrate such as a semiconductor wafer, for example. In some embodiments, beam modifiers 600a and 600b may form, or form a portion of, system 10 described above with respect to FIG. 3. For example, beam modifiers 600a and/or 600b may form a portion of an alignment sensor and/or an overlay detection sensor represented by system 10 (FIG. 3), as described herein. The alignment sensor and/or the overlay detection sensor may be configured for a semiconductor wafer, for example, and may be used in a semiconductor manufacturing process.

Beam modifiers 600a and/or 600b are configured to modify an amplitude, phase, and/or polarization of an incident radiation beam 604 from a radiation source (e.g., source 2 shown in FIG. 3 and described above) and/or a diffractor 602. Radiation beam 604 may be a broadband radiation beam, for example, and/or other radiation beams. Modifying an amplitude, phase, and/or polarization of the incident radiation beam facilitates focusing, tuning a focal length, and/or correcting an aberration of the radiation.

Beam modifiers 600a and/or 600b shown in FIG. 6 may be configured to receive incident radiation beam 604 from a radiation source (see FIG. 3) and/or diffractor 602, and transmit radiation 610a or 610b, respectively, having a modified amplitude, phase, and/or polarization. Diffractor 602 may be a grating and/or other diffractors. Diffractor 602 may be configured to separate beam 604 into specific wavelength ranges and direct the specific wavelength ranges to different sub-portions (601a or 601b, 603a or 603b, 605a or 605b, and/or 607a and 607b) of beam modifiers 600a and/or 600b. In some embodiments, a beam modifier 600a and/or 600b comprises a two dimensional (2D) array of adjacent sub-portions (601a or 601b, 603a or 603b, 605a or 605b, and/or 607a and 607b). In some embodiments, diffracting may comprise spatially separating incident radiation beam 604 by color into different wavelength groups and/or other diffracting.

The diffracted incident radiation beam 625 has a known wavelength range. This known wavelength range can be used to configure beam modifiers 600a and/or 600b. As shown in FIG. 6, in some embodiments, beam modifier 600a may be configured to collimate 620 transmitted radiation 610a. In some embodiments, beam modifier 610b may be configured to focus 630 transmitted radiation 610b toward a target 30. In some embodiments, a beam modifier (not shown in FIG. 6) may be configured to divide the diffracted incident radiation beam 625 into a series of non-overlapping wavelength radiation bands, each of which is focused at a different spot on a target 30, on a detector, and/or in other locations. Note that beam modifiers similar to and/or the same as beam modifiers 600a and/or 600b shown in FIG. 6 may similarly be configured to receive diffracted radiation from a (grating on a) target 30, and transmit the diffracted radiation toward a detector (e.g., in collimated, focused, divided, and/or other forms).

As shown in FIG. 6, beam modifiers 600a and 600b are configured to transmit separate narrower band sub-beams (651a and 651b, 653a and 653b, 655a and 655b, and 657a and 657b) of radiation 610a and 610b having a modified amplitude, phase, and/or polarization in comparison to diffracted incident radiation beam 625. Beam modifiers 600a and 600b comprise different sub-portions (601a or 601b, 603a or 603b, 605a or 605b, and/or 607a and 607b) configured to transmit the separate narrower band sub-beams of radiation (651a and 651b, 653a and 653b, 655a and 655b, and 657a and 657b). The different sub-portions (e.g., of the same metasurface) are configured for different non-overlapping radiation wavelength bandwidths within the known wavelength range. The diffracted incident radiation beam 625 received by beam modifiers 600a and/or 600b is spatially separated by color (different shades of gray in this example) into different wavelength groups, and directed toward color corresponding ones of the different sub-portions (601a or 601b, 603a or 603b, 605a or 605b, and/or 607a and 607b). In some embodiments, the diffracted incident radiation beam 625 received by a beam modifier 600a and/or 600b is spatially separated by color into different wavelength groups and directed toward color corresponding ones of the different sub-portions by diffractor 602 (e.g., the grating).

In some embodiments, a non-overlapping radiation wavelength bandwidth requirement may be a function of a grating pitch, for example. If the grating pitch is reduced, the diffraction angle increases so different wavelengths are further separated further. This causes overlap between different color bands to be reduced, so the required bandwidth is reduced, for example.

In some embodiments, the separate narrower band sub-beams of radiation (651a and 651b, 653a and 653b, 655a and 655b, and 657a and 657b) comprise locally bandwidth narrowed non-overlapping sub-beams of radiation having the modified amplitude, phase, and/or polarization. Each sub-portion may associated with a different color wavelength group and has a wavelength bandwidth for the associated color (shown in FIG. 6 by the different shades of gray), for example. In some embodiments, non-overlapping radiation wavelength bandwidths are fixed, and determined based on a pitch of a grating (e.g., diffractor 602) that generates diffracted incident radiation beam 625, a grating height, wavelength, a distance (h) between the grating and the beam modifier, the beam waist (or shape in general) and/or other information.

In some embodiments, as described above, a beam modifier 600a and/or 600b is a metasurface. The metasurface comprises nano-antennas, meta-atoms, scatterers, nano-particles, and/or other structures. In some embodiments, the different sub-portions (601a or 601b, 603a or 603b, 605a or 605b, and/or 607a and 607b) comprise adjacent local areas of a single unitary beam modifier 600a and/or 600b (e.g., metasurface) formed with nano-antennas, meta-atoms, scatters, and/or nano-particles configured for specific non-overlapping radiation wavelength bandwidths. In some embodiments, the nano-antennas, meta-atoms, scatterers, and/or nano-particles comprise blocks of material having heights, widths, lengths, and/or angles of rotation configured for a specific non-overlapping radiation wavelength bandwidth. In some embodiments, the nano-antennas, meta-atoms, scatterers, and/or nano-particles comprise free form shapes configured for a specific non-overlapping radiation wavelength bandwidth.

In some embodiments, as shown in FIG. 6, the different sub-portions (601b, 603b, 605b, and/or 607b) are configured to focus 630 transmitted radiation of a specific color (e.g., sub-beams of radiation 651b, 653b, 655b, and 657b) on a target 30 in a target location for that color. In some embodiments, the different sub-portions (601a, 603a, 605a, and/or 607a) are configured to collimate 620 transmitted radiation of a specific color to form a collimated beam of radiation for that color (e.g., sub-beams of radiation 651a, 653a, 655a, and 657a). In some embodiments, the different sub-portions are configured to disperse transmitted radiation of a specific color toward a target and a target location for that color (not shown in FIG. 6).

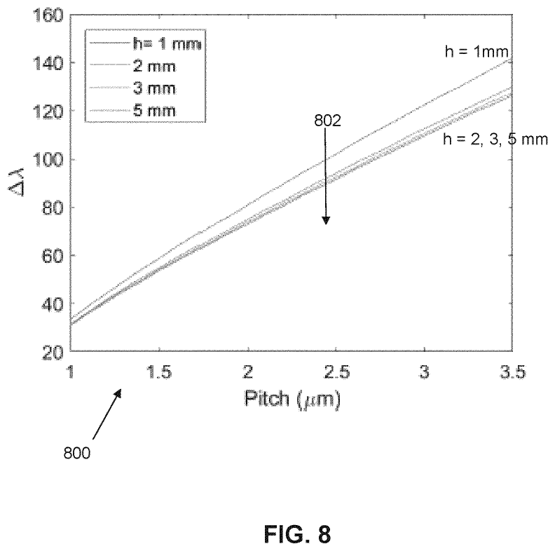

In some embodiments, the distance, h, between diffractor 602 (e.g., grating) and a beam modifier 600a or 600b is configured to be adjusted based on the grating pitch and/or different operating wavelengths that correspond to different color wavelength groups associated with the different sub-portions. In some embodiments, adjusting the height does not change the incident angle, but increasing the distance increases the required area of the metasurface. (FIG. 8 described below shows that adjusting the height helps to reduce the required bandwidth.)

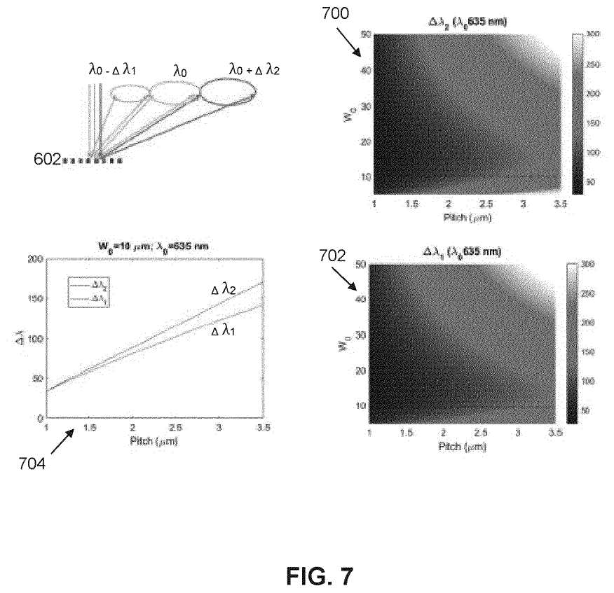

FIG. 7 schematically illustrates separating an incident radiation beam into wavelength bands. A beam modifier (e.g., a metasurface) phase distribution is a function of the wavelength of the incident radiation beam, λ, and/or other factors. FIG. 7 shows three beams with three different wavelengths: λ₀, λ₀−D λ₁, λ₀+D λ₂. The minimum D λ₁ and D λ₂ is sought to avoid the overlap between them. However, at each point on metasurface, (x,y), the operating wavelength is dictated by the diffraction angle, sin⁻¹ (λ/P) (when the incoming beam is normal incident on the grating), where P represents a pitch of a diffractor (e.g., diffractor 602 shown in FIG. 6). If an incident radiation beam is a plane wave and the metasurface is far (e.g., “h” in FIG. 6 is relatively large) from the grating (e.g., diffractor 602), at each point the metasurface operates at a single wavelength. But for a Gaussian input beam, at each point, the metasurface has a finite bandwidth, Aλ, which is a function of the beam waist (w₀), pitch size, and other parameters. FIG. 7 illustrates two different images 700 and 702 showing wavelength bandwidth ranges Δλ_{1,2} for different (diffractor/grating) pitches and incident radiation beam wastes. Three beams with three different wavelengths: λ₀, λ₀−D λ₁, λ₀+D λ₂ are shown. In FIG. 7, the local bandwidths of different sub-portions (shown in FIG. 6) of a metasurface are defined as the minimum difference in the wavelength, Δλ_{1,2}, to avoid the overlap between the adjacent diffracted Gaussian beams, and it is a function of the pitch, the wavelength, and height, h. The sensitivity to the wavelength and h are less than the sensitivity to pitch. In this calculation for the example shown in FIG. 7, h=1 mm is considered. For a beam waist of 10 μm (see the dotted line in images 700 and 702 for example), and with a pitch size of less than 2.5 μm, a local bandwidth of 100 nm is enough to cover a metrology system wavelength range of 400 nm to 900 nm, for example.

FIG. 7 shows results determined for a local bandwidth (e.g., a non-overlapping radiation wavelength bandwidth within the known wavelength range for one of the sub-portions of a beam modifier such as a metasurface) wavelength range, Δλ, as a function of the grating (e.g., diffractor 602 shown in FIG. 6) pitch, and the beam waist (e.g., of incident radiation beam 604 shown in FIG. 6) at a focus position, for a specific example wavelength of λ=635 nm. To simplify the determination for this example, FIG. 7 assumes that the incident beam (e.g., beam 604) is Gaussian and the grating (e.g., diffractor 602) is infinite. The bandwidth is not sensitive to the wavelength, and as shown in FIG. 7, it is almost similar on both sides of the operating wavelength, especially for smaller pitch sizes. It can be seen that a bandwidth of 100 nm is enough to cover the entire wavelength range of a typical metrology system if the pitch is less than 2 μm (e.g., as shown in plot 704).

FIG. 8 illustrates a plot 800 of local metasurface sub-portion bandwidth wavelength range, Δλ, as a function of the height, h (see FIG. 6—a distance between a diffractor 602 and a beam modifier 600a or 600b), for h=1, 2, 3, and 5 mm. As shown in FIG. 8, the line for h=1 mm is above and spaced apart from the lines for h=2, 3, and 5 mm. Increasing the height, h, helps to reduce (arrow 802) the required bandwidth for the same pitch. Phrased another way, the required bandwidth can be reduced by increasing the distance between a diffractor (e.g., a grating) and a beam modifier (e.g., a metasurface).

Metrology sensors need to work with diffractors (e.g., diffractor 602 shown in FIG. 6) having different pitches. Beam modifiers 600a and/or 600b are configured for a specific h×tan(sin⁻¹(λ/P)). The term sin⁻¹(λ/P) represents an angle of incident radiation, and h is the height described above. The distance from the center is the tangent of the angle times the height. This is the central location of the metasurface for each wavelength. When the pitch is changed, a corresponding change is needed only for the height. Phrased another way, if the pitch, P, of a diffractor changes, the beam modifier (e.g., metasurface) also needs to change accordingly. However, when the pitch is larger than 1.5 μm, tan(sin−1(λ/P)) can be approximated as λ/P. This means if the pitch is changed, only h must change to maintain the same h×tan(sin−1(λ/P)). Note that even if there is not exactly a one to one mapping, any errors can be compensated for by designing more broadband meta-atoms in a beam modifier (metasurface).

When the pitch is changed, the incident angle of incident radiation on a beam modifier (e.g., a metasurface) changes. Due to the coma aberration and/or other factors, a focal spot (e.g., on a target 30 shown in FIG. 6 and as described above) may be distorted. Aberrations can be corrected if the incident angle is changed up to about 25 degrees, for example. Such correction may be made using a beam modifier doublet and/or other devices.

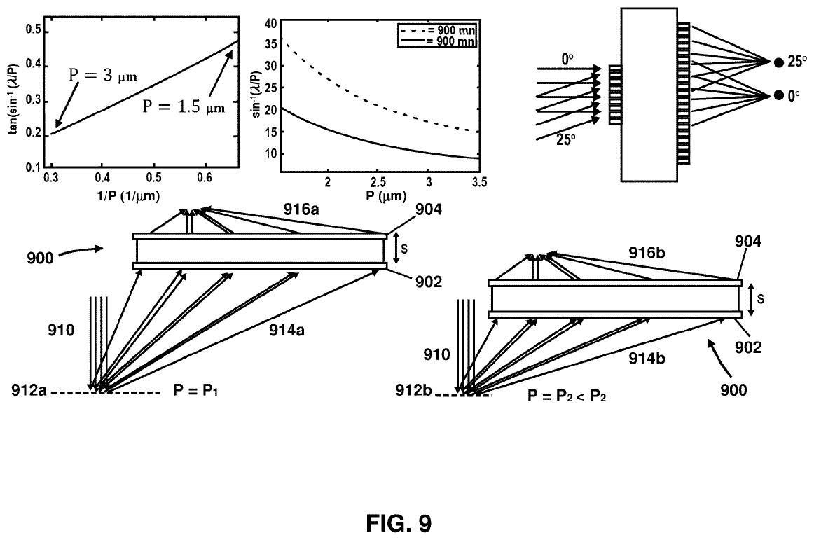

FIG. 9 illustrates a beam modifier (e.g., metasurface) doublet 900 (e.g., the beam modifier(s) described above may comprise a beam modifier doublet). In some embodiments, beam modifier doublet 900 comprises a first metasurface 902, and a second metasurface 904 spaced from first metasurface 902 along an optical path. FIG. 9 also illustrates an incident beam 910, diffractors 912a and 912b, diffracted incident beams 914a and 914b, and narrowband sub-beams of radiation 916a and 916b transmitted by sub-portions of first metasurface 902 and second metasurface 904 (see FIG. 6 for a description of sub-portions). A spacing, s, of second metasurface 904 from first metasurface 902 controls a focal length, corrects a defocus, and/or corrects a wave front aberration of different colored narrowband sub-beams of radiation 916a and 916b transmitted by the sub-portions. In addition, the spacing, s, may be adjusted based on the pitch, P, of diffractor 912a and/or 912b. In FIG. 9, the pitch, P₂, of diffractor 912b is less than the pitch, P₁, of diffractor 912a. The spacing, s, is changed for diffractor 912b relative to diffractor 912a in FIG. 9.

In some embodiments, a mechanical system (e.g., controlled by processor PRO shown in FIG. 3) is configured to adjust the spacing s between metasurfaces 902 and 904, between a metasurface 902 and diffractor 912a and/or 912b, and/or control other parameters. In some embodiments, a material fills a space between second metasurface 904 and first metasurface 902. The material may have a refractive index configured to be controlled to adjust a focus of beam modifier doublet 900. The refractive index of the material may be controlled by applying a voltage to the material or by applying an optical control signal to the material, for example. The material may comprise liquid crystals, an electro-optic material, and/or other materials. The electro-optic materials comprise some polymers, lithium niobate, aluminum nitride, etc. A liquid crystal may be any commercially available liquid crystal, including for example E7® from Merck. The refractive index of the material may be controlled by applying a voltage to the material or by applying an optical control signal, for example. Note that an active material is not strictly required, but may be included. As described herein, the doublet can move.

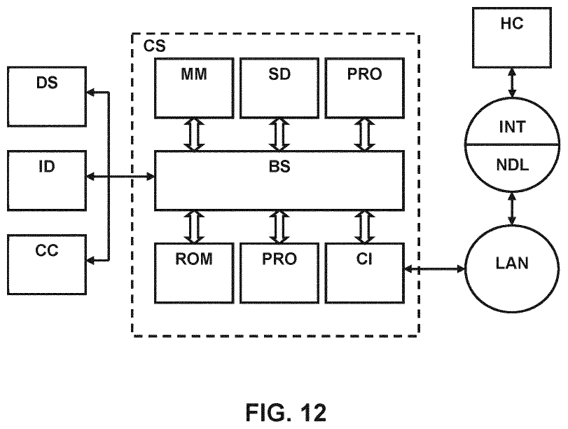

In some embodiments, movement may be controlled electronically by a processor, such as processor PRO shown in FIG. 3 (and also in FIG. 12 discussed below). Processor PRO may be included in a computing system (e.g., CS in FIG. 12) and may operate based on computer or machine readable instructions MRI (e.g., as described below related to FIG. 12). Electronic communication may occur by transmitting electronic signals between separate components, transmitting data between separate components, transmitting values between separate components, and/or other communication. The components of a metrology system may communicate via wires or wirelessly via a network, such as the Internet or the Internet in combination with various other networks, like local area networks, cellular networks, or personal area networks, internal organizational networks, and/or other networks.

In some embodiments, one or more actuators may be coupled to and configured to move one or more components described above. The actuators may be coupled to one or more of these components by adhesive, clips, clamps, screws, a collar, and/or other mechanisms. The actuators may be configured to be controlled electronically. Individual actuators may be configured to convert an electrical signal into mechanical displacement. The mechanical displacement is configured to move a component, such as one or more metasurfaces. As an example, one or more of the actuators may be piezoelectric. One or more processors PRO may be configured to control the actuators. One or more processors PRO may be configured to individually control each of the one or more actuators.

As described above, aberrations can be corrected if the angle of incident radiation is changed up to about 25 degrees (FIG. 9, top right panel) using metasurface doublet 900. If the pitch P varies from 1.5 to 3 μm, the incident angle for the two extremes of the spectrum changes less than 15 degrees (FIG. 9, top middle). Note that the spot is shifted, but by moving the detector of the metrology system, the spot shift can be corrected. Since the diffractor (e.g., grating) pitch does not typically change across a substrate, the mechanical movement of the detector does not slow down the measurement process. The top left panel in FIG. 9 illustrates how the incident angle changes as the pitch changes. For a wide range of pitches, the angle of incident changes only 20 degrees, showing that the doublet functions as intended.

For some applications, radiation beam dispersion may be desirable. In some embodiments, a beam modifier may be configured for beam dispersion instead of beam focusing or beam collimation. In these embodiments, light is still being focused, but each color is focused at a different spot. In some embodiments, a metasurface is still dispersive, but the metasurface geometrical dispersion compensates for material dispersion. Here, the metasurface geometrical dispersion enhances the material dispersion. Thus, different wavelengths are separated.

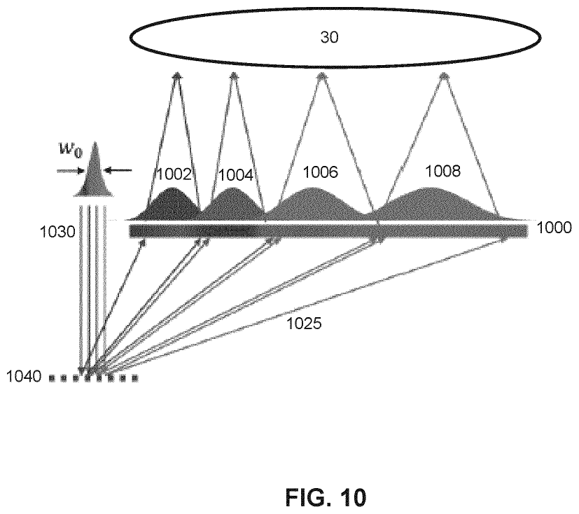

FIG. 10 illustrates a beam modifier 1000 (e.g., a metasurface) configured to divide the diffracted incident radiation beam 1025 (after diffraction of incident radiation beam 1030 by diffractor 1040) into a series of non-overlapping wavelength bands of radiation 1002, 1004, 1006, 1008, each of which is focused at a different spot on a target 30, on a detector, and/or in other locations. Instead of reducing spectral dispersion, beam modifier 1000 is configured to enhance spectral dispersion. In some embodiments, beam modifier 1000 may be a hyper-dispersive metasurface, for example. Beam modifier 1000 is configured to spatially demultiplex wavelength bands of incident radiation beam 1030 as shown in FIG. 10. This type of metasurface is useful for many applications, such as integrated optics alignment sensors, in which a capturing grating coupler has a narrow bandwidth and the overlap between beams hinders capturing the beams efficiently. This metasurface is also helpful for demultiplexing the beams, and each beam can be coupled to a different fiber or waveguide (or a detector in general). By focusing different wavelengths at different spots, smaller grating couplers can be used, which are easier to separate from each other sufficiently (e.g., so that they function properly).

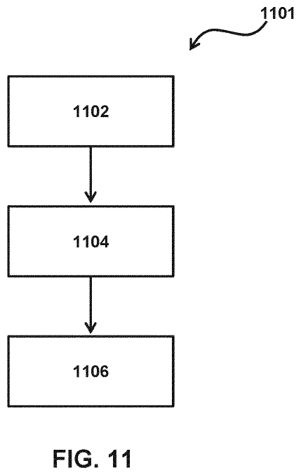

FIG. 11 illustrates a metrology method 1101. In some embodiments, method 1101 is performed as part of an overlay and/or alignment sensing operation in a semiconductor device manufacturing process, for example. In some embodiments, one or more operations of method 1101 may be implemented in or by a metrology system such as system 10 illustrated in FIG. 3, a beam modifier (e.g., a metasurface) such as beam modifier 600a and/or 600b illustrated in FIG. 6, a computer system (e.g., as illustrated in FIG. 12 and described below), and/or in or by other systems, for example. In some embodiments, method 1101 comprises generating and diffracting (operation 1102) an incident radiation beam, receiving and transmitting (operation 1104) a diffracted incident radiation beam, generating (operation 1106) a detection signal, and/or other operations. The diffractor may be a grating and/or other diffractors as described above, for example.

The operations of method 1101 are intended to be illustrative. In some embodiments, method 1101 may be accomplished with one or more additional operations not described, and/or without one or more of the operations discussed. For example, in some embodiments, method 1101 may include an additional operation comprising determining overlay and/or alignment for a semiconductor wafer, and determining an adjustment for a semiconductor device manufacturing process. Additionally, the order in which the operations of method 1101 are illustrated in FIG. 11 and described herein is not intended to be limiting.

In some embodiments, one or more portions of method 1101 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1101 in response to instructions stored electronically on an electronic storage medium. The one or more processing devices may include one or more devices configured through hardware, firmware, and/or software to be specifically designed for execution of one or more of the operations of method 1101 (e.g., see discussion related to FIG. 12 below).

At operation 1102, an incident radiation beam is generated. The incident radiation beam is generated by a radiation source that is part of the metrology system. In addition, operation 1102 may include diffracting, with a diffractor, the incident radiation beam. In some embodiments, the radiation source is the same as or similar to illumination source 2 shown in FIG. 3 and described above. The incident radiation beam may be diffracted with a diffractor similar to and/or the same as diffractor 602 shown in FIG. 6.

In some embodiments, the metrology system and/or the diffractor comprises a wavelength-division multiplexer in a multi-core fiber, a blazed grating, and/or other components. Operation 1102 may comprise spatially separating the incident radiation received by the diffractor by color into different wavelength groups using wavelength-division multiplexing in the multi-core fiber, and/or using the blazed grating, for example.

At operation 1104, a diffracted incident radiation beam is received with a beam modifier. The diffracted incident radiation beam is received from the radiation source and the diffractor. The diffracted incident radiation beam has a known wavelength range. Operation 1104 also includes transmitting, with the beam modifier, separate narrower band sub-beams of radiation having a modified amplitude, phase, and/or polarization in comparison to the diffracted incident radiation beam. The beam modifier comprises different sub-portions configured to transmit the separate narrower band sub-beams of radiation. The different sub-portions are configured for different non-overlapping radiation wavelength bandwidths within the known wavelength range. The diffracted incident radiation beam received by the beam modifier is spatially separated by color into different wavelength groups, and directed toward color corresponding ones of the different sub-portions. In some embodiments, the diffracted incident radiation beam received by the beam modifier is spatially separated by color into different wavelength groups and directed toward color corresponding ones of the different sub-portions by the diffractor (e.g., the grating). A non-overlapping radiation wavelength bandwidth requirement may be a function of a grating pitch, for example. In some embodiments, the beam modifier focuses the diffracted incident radiation beam, collimates the diffracted incident radiation beam, or divides the diffracted incident radiation beam into a series of non-overlapping radiation wavelength bands, each of which is focused at a different spot on a target.

In some embodiments, the separate narrower band sub-beams of radiation comprise locally bandwidth narrowed non-overlapping sub-beams of radiation having the modified amplitude, phase, and/or polarization. Each sub-portion may associated with a different color wavelength group and has a wavelength bandwidth for the associated color, for example.

In some embodiments, the beam modifier is a metasurface, and the metasurface comprises nano-antennas, meta-atoms, scatterers, nano-particles, and/or other structures. In some embodiments, the different sub-portions comprise adjacent local areas of a single unitary metasurface formed with nano-antennas, meta-atoms, scatters, and/or nano-particles configured for specific non-overlapping radiation wavelength bandwidths. In some embodiments, the nano-antennas, meta-atoms, scatterers, and/or nano-particles comprise blocks of material having heights, widths, lengths, and/or angles of rotation configured for a specific non-overlapping radiation wavelength bandwidth. In some embodiments, the nano-antennas, meta-atoms, scatterers, and/or nano-particles comprise free form shapes configured for a specific non-overlapping radiation wavelength bandwidth.

In some embodiments, the different sub-portions are configured to focus transmitted radiation of a specific color on a target in a target location for that color. In some embodiments, the different sub-portions are configured to collimate transmitted radiation of a specific color to form a collimated beam of radiation for that color. In some embodiments, the different sub-portions are configured to disperse transmitted radiation of a specific color toward a target and a target location for that color.

In some embodiments, the distance between the diffractor (e.g., grating) and the beam modifier is configured to be adjusted based on the grating pitch and/or different operating wavelengths that correspond to different color wavelength groups associated with the different sub-portions. In some embodiments, adjusting the distance between the grating and the beam modifier changes an angle of incidence of the diffracted incident radiation beam on the beam modifier.

In some embodiments, the beam modifier comprises a two dimensional (2D) array of adjacent sub-portions. In some embodiments, the non-overlapping radiation wavelength bandwidths are fixed, and determined based on a pitch of a grating (e.g., the diffractor) that generates the diffracted incident radiation beam, a grating height, wavelength, and/or a distance between the grating and the beam modifier.

In some embodiments, the beam modifier comprises a first metasurface, and a second metasurface spaced from the first metasurface along an optical path. A spacing of the second metasurface from the first metasurface controls a focal length, corrects a defocus, and/or corrects a wave front aberration of different colored narrowband sub-beams of radiation transmitted by the sub-portions. A mechanical system (e.g., controlled by processor PRO) is configured to adjust the spacing between metasurfaces, between a metasurface and the grating, and/or control other parameters.

In some embodiments, a material fills a space between the second metasurface and the first metasurface. The material may have a refractive index configured to be controlled to adjust a focus of the beam modifier. Operation 1104 may include controlling the refractive index of the material by applying a voltage to the material or by applying an optical control signal to the material, for example.

In some embodiments, the beam modifier may comprise an array of beam modifiers. The array of beam modifiers may include first portions, second portions, and/or other beam modifiers. The first portions are configured to receive the incident radiation beam from the radiation source, and transmit radiation having a modified amplitude, phase, and/or polarization, and focus the transmitted radiation toward a target. The second portions are configured to receive diffracted radiation from the target, and transmit the diffracted radiation toward a detector. In some embodiments, the first portions and the second portions overlap and/or are intermixed on a unitary body, for example. In some embodiments, the first portions and the second portions are included in a single metasurface. In some embodiments, the first portions and the second portions comprise a plurality of metasurfaces (e.g., separate bodies or simply individual metasurfaces within the body).

In some embodiments, the radiation may be directed by the beam modifier onto multiple targets on a substrate such as a semiconductor wafer, a single target, sub-portions (e.g., something less than the whole) of a target, and/or onto a substrate in other ways. In some embodiments, the radiation may be directed onto the target in a time varying manner. For example, the radiation may be rastered over a target (e.g., by moving the target under the radiation) such that different portions of the target are irradiated at different times. As another example, characteristics of the radiation (e.g., wavelength, intensity, etc.) may be varied. This may create time varying data envelopes, or windows, for analysis. The data envelopes may facilitate analysis of individual sub-portions of a target, comparison of one portion of a target to another and/or to other targets (e.g., in other layers), and/or other analysis.

At operation 1106, a detection signal is generated. The detection signal may be generated based on detected reflected radiation from diffraction grating target(s), as described above. The detection signal is generated by a sensor (such as detector 4 in FIG. 3, a camera, and/or other sensors) based on radiation received by the sensor. The detection signal comprises measurement information pertaining to the target(s). For example, the detection signal may be an overlay and/or alignment signal comprising overlay and/or alignment measurement information, and/or other metrology signals. The measurement information (e.g., an overlay value, an alignment value, and/or other information) may be determined using principles of interferometry and/or other principles.

The detection signal comprises an electronic signal that represents and/or otherwise corresponds to the radiation reflected from the target(s). Diffracted radiation from a target may comprise + and − first order diffracted radiation.

The detection signal may indicate a metrology value associated with a diffraction grating target, for example, and/or other information. Generating the detection signal comprises sensing the reflected radiation and converting the sensed reflected radiation into the electronic signal. In some embodiments, generating the detection signal comprises sensing different portions of the reflected radiation from different areas and/or different geometries of the target, and/or multiple targets, and combining the different portions of the reflected radiation to form the detection signal. This may include generating and/or analyzing one or more images of a target, using the radiation described herein. This sensing and converting may be performed by components similar to and/or the same as detector 4 and/or processors PRO shown in FIG. 3, and/or other components.

In some embodiments, method 1101 comprises detecting reflected radiation from one or more diffraction grating targets. Detecting reflected radiation comprises detecting one or more phase and/or amplitude (intensity) shifts in reflected radiation from one or more geometric features of the target(s). The one or more phase and/or amplitude shifts correspond to one or more dimensions of a target. For example, the phase and/or amplitude of reflected radiation from one side of a target is different relative to the phase and/or amplitude of reflected radiation from another side of the target.

Detecting the one or more phase and/or amplitude (intensity) shifts in the reflected radiation from the target comprises measuring local phase shifts (e.g., local phase deltas) and/or amplitude variations that correspond to different portions of a target. For example, the reflected radiation from a specific area of a target may comprise a sinusoidal waveform having a certain phase and/or amplitude. The reflected radiation from a different area of the target (or a target in a different layer) may also comprise a sinusoidal waveform, but one with a different phase and/or amplitude. Detected reflected radiation also comprises measuring a phase and/or amplitude difference in reflected radiation of different diffraction orders. Detecting the one or more local phase and/or amplitude shifts may be performed using Hilbert transformations, for example, and/or other techniques. Interferometry techniques and/or other operations may be used to measure phase and/or amplitude differences in reflected radiation of different diffraction orders.

In some embodiments, method 1101 comprises determining an adjustment for a semiconductor device manufacturing process. In some embodiments, method 1101 includes determining one or more semiconductor device manufacturing process parameters. The one or more semiconductor device manufacturing process parameters may be determined based on one or more detected phase and/or amplitude variations, an overlay and/or alignment value indicated by the detection signal, and/or other similar systems, and/or other information. The one or more parameters may include a parameter of the radiation (the radiation used for metrology), an overlay value, an alignment value, a metrology inspection location on a layer of a semiconductor device structure, a radiation beam trajectory across a target, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

In some embodiments, method 1101 includes determining a process adjustment based on the one or more determined semiconductor device manufacturing process parameters, adjusting a semiconductor device manufacturing apparatus based on the determined adjustment, and/or other operations. For example, if a determined metrology measurement is not within process tolerances, the out of tolerance measurement may be caused by one or more manufacturing processes whose process parameters have drifted and/or otherwise changed so that the process is no longer producing acceptable devices (e.g., measurements may breach a threshold for acceptability). One or more new or adjusted process parameters may be determined based on the measurement determination. The new or adjusted process parameters may be configured to cause a manufacturing process to again produce acceptable devices.

For example, a new or adjusted process parameter may cause a previously unacceptable measurement value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of method 1101), for example. In some embodiments, method 1401 may include electronically adjusting an apparatus (e.g., based on the determined process parameters). Electronically adjusting an apparatus may include sending an electronic signal, and/or other communications to the apparatus, for example, which causes a change in the apparatus. The electronic adjustment may include changing a setting on the apparatus, for example, and/or other adjustments.

FIG. 12 is a diagram of an example computer system CS that may be used for one or more of the operations described herein. Computer system CS includes a bus BS or other communication mechanism for communicating information, and a processor PRO (or multiple processors similar to and/or the same as processor PRO shown in FIG. 3) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a flat panel or touch panel display or a cathode ray tube (CRT) for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Various embodiments of the present systems and methods are disclosed in the subsequent list of numbered clauses. In the following, further features, characteristics, and exemplary technical solutions of the present disclosure will be described in terms of clauses that may be optionally claimed in any combination:
1. A beam modifier, the beam modifier configured to receive a diffracted incident radiation beam from a radiation source, the diffracted incident radiation beam having a known wavelength range, the beam modifier configured to transmit separate narrower band sub-beams of radiation having a modified amplitude, phase, and/or polarization in comparison to the diffracted incident radiation beam, wherein the beam modifier comprises different sub-portions configured to transmit the separate narrower band sub-beams of radiation, the different sub-portions configured for different non-overlapping radiation wavelength bandwidths within the known wavelength range.
2. The beam modifier of clause 1, wherein the beam modifier is a metasurface, and the metasurface comprises nano-antennas, meta-atoms, scatterers, and/or nano-particles.
3. The beam modifier of any of the previous clauses, wherein the separate narrower band sub-beams of radiation comprise locally bandwidth narrowed non-overlapping sub-beams of radiation having the modified amplitude, phase, and/or polarization, and wherein each sub-portion is associated with a different color wavelength group and has a wavelength bandwidth for the associated color.
4. The beam modifier of any of the previous clauses, wherein the different sub-portions comprise adjacent local areas of a single unitary metasurface formed with nano-antennas, meta-atoms, scatterers, and/or nano-particles configured for specific non-overlapping radiation wavelength bandwidths.
5. The beam modifier of any of the previous clauses, wherein the nano-antennas, meta-atoms, scatterers, and/or nano-particles comprise blocks of material having heights, widths, lengths, and/or angles of rotation configured for a specific non-overlapping radiation wavelength bandwidth.
6. The beam modifier of any of the previous clauses, wherein the nano-antennas, meta-atoms, scatterers, and/or nano-particles comprise free form shapes configured for a specific non-overlapping radiation wavelength bandwidth.
7. The beam modifier of any of the previous clauses, wherein the different sub-portions are configured to focus transmitted radiation of a specific color on a target in a target location for that color.
8. The beam modifier of any of the previous clauses, wherein the different sub-portions are configured to collimate transmitted radiation of a specific color to form a collimated beam of radiation for that color.
9. The beam modifier of any of the previous clauses, wherein the different sub-portions are configured to disperse transmitted radiation of a specific color toward a target and a target location for that color.
10. The beam modifier of any of the previous clauses, wherein the beam modifier comprises a two dimensional (2D) array of adjacent sub-portions.
11. The beam modifier of any of the previous clauses, wherein the non-overlapping radiation wavelength bandwidths are fixed, and determined based on a pitch of a grating that generates the diffracted incident radiation beam, a grating height, wavelength, and/or a distance between the grating and the beam modifier.
12. The beam modifier of any of the previous clauses, wherein the distance between the grating and the beam modifier is configured to be adjusted based on the grating pitch and/or different operating wavelengths that correspond to different color wavelength groups associated with the different sub-portions.
13. The beam modifier of any of the previous clauses, wherein adjusting the distance between the grating and the beam modifier changes an angle of incidence of the diffracted incident radiation beam on the beam modifier.
14. The beam modifier of any of the previous clauses, wherein the beam modifier comprises a first metasurface, and a second metasurface spaced from the first metasurface along an optical path.
15. The beam modifier of any of the previous clauses, wherein a spacing of the second metasurface from the first metasurface controls a focal length, corrects a defocus, and/or corrects a wave front aberration of different colored narrowband sub-beams of radiation transmitted by the sub-portions.
16. The beam modifier of any of the previous clauses, wherein a mechanical system is configured to adjust the spacing.
17. The beam modifier of any of the previous clauses, wherein the beam modifier focuses the diffracted incident radiation beam, collimates the diffracted incident radiation beam, or divides the diffracted incident radiation beam into a series of non-overlapping radiation wavelength bands, each of which is focused at a different spot on a target.
18. A metrology system, comprising: a radiation source configured to generate an incident radiation beam; a diffractor configured to diffract the incident radiation beam; and a beam modifier configured to receive a diffracted incident radiation beam from the radiation source and the diffractor, the diffracted incident radiation beam having a known wavelength range, the beam modifier configured to transmit separate narrower band sub-beams of radiation having a modified amplitude, phase, and/or polarization in comparison to the diffracted incident radiation beam, wherein the beam modifier comprises different sub-portions configured to transmit the separate narrower band sub-beams of radiation, the different sub-portions configured for different non-overlapping radiation wavelength bandwidths within the known wavelength range, wherein the diffracted incident radiation beam received by the beam modifier is spatially separated by color into different wavelength groups, and directed toward color corresponding ones of the different sub-portions.
19. The system of clause 18, wherein the diffractor comprises a grating, wherein the diffracted incident radiation beam received by the beam modifier is spatially separated by color into different wavelength groups and directed toward color corresponding ones of the different sub-portions by the grating, and wherein a non-overlapping radiation wavelength bandwidth requirement is a function of a grating pitch.
20. The system of any of the previous clauses, further comprising a detector configured to receive reflected radiation after it has reflected off a target, and generate a detection signal, the reflected radiation comprising the separate narrower band sub-beams of radiation after they have been reflected off the target.
21. The system of any of the previous clauses, wherein the metrology system forms a portion of an alignment sensor and/or an overlay detection sensor, and wherein the alignment sensor and/or the overlay detection sensor is configured for a semiconductor wafer, and is used in a semiconductor manufacturing process.
22. A method for transmitting radiation, the method comprising: receiving, with a beam modifier, a diffracted incident radiation beam from a radiation source, the diffracted incident radiation beam having a known wavelength range, and transmitting, with the beam modifier, separate narrower band sub-beams of radiation having a modified amplitude, phase, and/or polarization in comparison to the diffracted incident radiation beam, wherein the beam modifier comprises different sub-portions configured to transmit the separate narrower band sub-beams of radiation, the different sub-portions configured for different non-overlapping radiation wavelength bandwidths within the known wavelength range.
23. The method of clause 22, wherein the beam modifier is a metasurface, and the metasurface comprises nano-antennas, meta-atoms, scatterers, and/or nano-particles.
24. The method of any of the previous clauses, wherein the separate narrower band sub-beams of radiation comprise locally bandwidth narrowed non-overlapping sub-beams of radiation having the modified amplitude, phase, and/or polarization, and wherein each sub-portion is associated with a different color wavelength group and has a wavelength bandwidth for the associated color.
25. The method of any of the previous clauses, wherein the different sub-portions comprise adjacent local areas of a single unitary metasurface formed with nano-antennas, meta-atoms, or nano-particles configured for specific non-overlapping radiation wavelength bandwidths.
26. The method of any of the previous clauses, wherein the nano-antennas, meta-atoms, scatterers, and/or nano-particles comprise blocks of material having heights, widths, lengths, and/or angles of rotation configured for a specific non-overlapping radiation wavelength bandwidth.
27. The method of any of the previous clauses, wherein the nano-antennas, meta-atoms, scatterers, and/or nano-particles comprise free form shapes configured for a specific non-overlapping radiation wavelength bandwidth.
28. The method of any of the previous clauses, wherein the different sub-portions are configured to focus transmitted radiation of a specific color on a target in a target location for that color.
29. The method of any of the previous clauses, wherein the different sub-portions are configured to collimate transmitted radiation of a specific color to form a collimated beam of radiation for that color.
30. The method of any of the previous clauses, wherein the different sub-portions are configured to disperse transmitted radiation of a specific color toward a target and a target location for that color.
31. The method of any of the previous clauses, wherein the beam modifier comprises a two dimensional (2D) array of adjacent sub-portions.
32. The method of any of the previous clauses, wherein the non-overlapping radiation wavelength bandwidths are fixed, and determined based on a pitch of a grating that generates the diffracted incident radiation beam, a grating height, wavelength, and/or a distance between the grating and the beam modifier.
33. The method of any of the previous clauses, further comprising adjusting the distance between the grating and the beam modifier based on the grating pitch and/or different operating wavelengths that correspond to different color wavelength groups associated with the different sub-portions.
34. The method of any of the previous clauses, wherein adjusting the distance between the grating and the beam modifier changes an angle of incidence of the diffracted incident radiation beam on the beam modifier.
35. The method of any of the previous clauses, wherein the beam modifier comprises a first metasurface, and a second metasurface spaced from the first metasurface along an optical path.
36. The method of any of the previous clauses, wherein a spacing of the second metasurface from the first metasurface controls a focal length, corrects a defocus, and/or corrects a wave front aberration of different colored narrowband sub-beams of radiation transmitted by the sub-portions.
37. The method of any of the previous clauses, wherein a mechanical system is configured to adjust the spacing.
38. The method of any of the previous clauses, wherein the beam modifier focuses the diffracted incident radiation beam, collimates the diffracted incident radiation beam, or divides the diffracted incident radiation beam into a series of non-overlapping radiation wavelength bands, each of which is focused at a different spot on a target.
39. A metrology method, comprising: generating, with a radiation source, an incident radiation beam; diffracting, with a diffractor, the incident radiation beam; and receiving, with a beam modifier, a diffracted incident radiation beam from the radiation source and the diffractor, the diffracted incident radiation beam having a known wavelength range; and transmitting, with the beam modifier, separate narrower band sub-beams of radiation having a modified amplitude, phase, and/or polarization in comparison to the diffracted incident radiation beam, wherein the beam modifier comprises different sub-portions configured to transmit the separate narrower band sub-beams of radiation, the different sub-portions configured for different non-overlapping radiation wavelength bandwidths within the known wavelength range, and wherein the diffracted incident radiation beam received by the beam modifier is spatially separated by color into different wavelength groups, and directed toward color corresponding ones of the different sub-portions.
40. The method of any of the previous clauses, wherein the diffractor comprises a grating, wherein the diffracted incident radiation beam received by the beam modifier is spatially separated by color into different wavelength groups and directed toward color corresponding ones of the different sub-portions by the grating, and wherein a non-overlapping radiation wavelength bandwidth requirement is a function of a grating pitch.
41. The method of any of the previous clauses, further comprising receiving, with a detector, reflected radiation after it has reflected off a target, and generating a detection signal, the reflected radiation comprising the separate narrower band sub-beams of radiation after they have been reflected off the target.
42. The method of any of the previous clauses, wherein the radiation source, the diffractor, and the beam modifier are included in a metrology system, and the metrology system forms a portion of an alignment sensor and/or an overlay detection sensor, and wherein the alignment sensor and/or the overlay detection sensor is configured for a semiconductor wafer, and is used in a semiconductor manufacturing process.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1. A beam modifier configured to receive a diffracted incident radiation beam from a radiation source, the diffracted incident radiation beam having a known wavelength range, the beam modifier configured to transmit separate narrower band sub-beams of radiation having a modified amplitude, phase, and/or polarization in comparison to the diffracted incident radiation beam,
wherein the beam modifier comprises different sub-portions configured to transmit the separate narrower band sub-beams of radiation, the different sub-portions configured for different non-overlapping radiation wavelength bandwidths within the known wavelength range.

2. The beam modifier of claim 1, wherein the beam modifier is a metasurface, and the metasurface comprises nano-antennas, meta-atoms, scatterers, and/or nano-particles.

3. The beam modifier of claim 1, wherein the separate narrower band sub-beams of radiation comprise locally bandwidth narrowed non-overlapping sub-beams of radiation having the modified amplitude, phase, and/or polarization, and wherein each sub-portion is associated with a different color wavelength group and has a wavelength bandwidth for the associated color.

4. The beam modifier of claim 1, wherein the different sub-portions comprise adjacent local areas of a single unitary metasurface formed with nano-antennas, meta-atoms, scatterers, and/or nano-particles configured for specific non-overlapping radiation wavelength bandwidths.

5. The beam modifier of claim 4, wherein the nano-antennas, meta-atoms, scatterers, and/or nanoparticles comprise blocks of material having heights, widths, lengths, and/or angles of rotation configured for a specific non-overlapping radiation wavelength bandwidth.

6. The beam modifier of claim 4, wherein the nano-antennas, meta-atoms, scatterers, and/or nanoparticles comprise free form shapes configured for a specific non-overlapping radiation wavelength bandwidth.

7. The beam modifier of claim 1, wherein the different sub-portions are configured to focus transmitted radiation of a specific color on a target in a target location for that color.

8. The beam modifier of claim 1, wherein the different sub-portions are configured to collimate transmitted radiation of a specific color to form a collimated beam of radiation for that color.

9. The beam modifier of claim 1, wherein the different sub-portions are configured to disperse transmitted radiation of a specific color toward a target and a target location for that color.

10. The beam modifier of claim 1, wherein the beam modifier comprises a two dimensional (2D) array of adjacent sub-portions.

11. The beam modifier of claim 1, wherein the non-overlapping radiation wavelength bandwidths are fixed, and determined based on a pitch of a grating that generates the diffracted incident radiation beam, a grating height, wavelength, and/or a distance between the grating and the beam modifier.

12. The beam modifier of claim 11, wherein the distance between the grating and the beam modifier is configured to be adjusted based on the grating pitch and/or different operating wavelengths that correspond to different color wavelength groups associated with the different sub-portions.

13. The beam modifier of claim 12, wherein adjustment of the distance between the grating and the beam modifier changes an angle of incidence of the diffracted incident radiation beam on the beam modifier.

14. The beam modifier of claim 13, wherein the beam modifier comprises a first metasurface, and a second metasurface spaced from the first metasurface along an optical path.

15. The beam modifier of claim 14, wherein a spacing of the second metasurface from the first metasurface controls a focal length, corrects a defocus, and/or corrects a wave front aberration of different colored narrowband sub-beams of radiation transmitted by the sub-portions.

16. The beam modifier of claim 15, wherein a mechanical system is configured to adjust the spacing.

17. The beam modifier of claim 1, wherein the beam modifier focuses the diffracted incident radiation beam, collimates the diffracted incident radiation beam, or divides the diffracted incident radiation beam into a series of non-overlapping radiation wavelength bands, each of which is focused at a different spot on a target.

18. A metrology system, comprising:
a diffractor configured to diffract an incident radiation beam; and
a beam modifier configured to receive a diffracted incident radiation beam from the diffractor, the diffracted incident radiation beam having a known wavelength range, the beam modifier configured to transmit separate narrower band sub-beams of radiation having a modified amplitude, phase, and/or polarization in comparison to the diffracted incident radiation beam, wherein the beam modifier comprises different sub-portions configured to transmit the separate narrower band sub-beams of radiation, the different sub-portions configured for different non-overlapping radiation wavelength bandwidths within the known wavelength range, wherein the diffracted incident radiation beam received by the beam modifier is spatially separated by color into different wavelength groups, and directed toward color corresponding ones of the different sub-portions.

19. The system of claim 18, wherein the diffractor comprises a grating, wherein the diffracted incident radiation beam received by the beam modifier is spatially separated by color into different wavelength groups and directed toward color corresponding ones of the different sub-portions by the grating, and wherein a non-overlapping radiation wavelength bandwidth requirement is a function of a grating pitch.

20. A method for transmitting radiation, the method comprising:
receiving, with a beam modifier, a diffracted incident radiation beam from a radiation source, the diffracted incident radiation beam having a known wavelength range, and
transmitting, with the beam modifier, separate narrower band sub-beams of radiation having a modified amplitude, phase, and/or polarization in comparison to the diffracted incident radiation beam, wherein the beam modifier comprises different sub-portions configured to transmit the separate narrower band sub-beams of radiation, the different sub-portions configured for different non-overlapping radiation wavelength bandwidths within the known wavelength range.
